(19) United States
(12) Patent Application Publication
(10) Pub. No.: US 2025/0226343 A1
(43) Pub. Date: Jul. 10, 2025

(54) ELECTRONIC DEVICE

(71) Applicant: Innolux Corporation, Miaoli County (TW)

(72) Inventor: Chia-Ping Tseng, Miaoli County (TW)

(73) Assignee: Innolux Corporation, Miaoli County (TW)

(21) Appl. No.: 18/981,661

(22) Filed: Dec. 16, 2024

Related U.S. Application Data
(60) Provisional application No. 63/619,318, filed on Jan. 10, 2024.

(30) Foreign Application Priority Data
Sep. 23, 2024 (CN) 202411326624.2

(51) Int. Cl. H01L 23/00; H01L 23/66; H10D 86/40; H10D 86/60

(52) U.S. Cl. CPC H01L 24/13; H01L 24/11; H10D 86/441; H01L 23/66; H01L 2223/6677; H01L 2224/11464; H01L 2224/13006; H01L 2224/13155; H01L 2224/13562; H01L 2224/1357; H01L 2224/13944; H01L 2924/365; H10D 86/481; H10D 86/60

(57) ABSTRACT

An electronic device including a substrate, a conductive structure, an insulating layer, and a bonding structure. The conductive structure is disposed on the substrate and includes a first conductive layer, a second conductive layer, an intermetallic compound, and a third conductive layer stacked in such a sequence, in which the intermetallic compound includes a first opening exposing the second conductive layer. The insulating layer is disposed on the conductive structure and includes a second opening exposing the second conductive layer of the conductive structure. The bonding structure is disposed on the insulating layer, in which the bonding structure is electrically connected to the conductive structure through the second opening of the insulating layer. A first width of the second opening of the insulating layer in a first direction is different from a second width of the first opening of the intermetallic compound in the first direction.

### CROSS-REFERENCE TO RELATED APPLICATION

This application claims the priority benefits of U.S. provisional application Ser. No. 63/619,318, filed on Jan. 10, 2024, and China application serial no. 202411326624.2, filed on Sep. 23, 2024. The entirety of each of the above-mentioned patent applications is hereby incorporated by reference herein and made a part of this specification.

### BACKGROUND

### Technical Field

The disclosure relates to an electronic device, and particularly relates to an antenna device.

### Description of Related Art

In the electronic device, a conductive structure including multiple conductive layers (such as stacked layers of titanium nitride layers, copper layers, and titanium nitride layers) is set up to apply to the bonding process of the BEOL process. However, if the electronic device undergoes a relatively high-temperature process during the formation of the electronic device, the titanium in the titanium nitride layer included in the conductive structure diffuses toward the direction close to the copper layer, resulting in the formation of an intermetallic compound including copper and titanium. The intermetallic compound is difficult to remove through the etching process used during the formation of the electronic device, which affects the electrical connection between the bonding structure and the conductive structure, leading to a decrease in the reliability of the ultimately formed electronic device.

### SUMMARY

The disclosure provides an electronic device, whose reliability can be improved.

According to some embodiments of the disclosure, the electronic device includes a substrate, a conductive structure, an insulating layer, and a bonding structure. The conductive structure is disposed on the substrate and includes a first conductive layer, a second conductive layer, an intermetallic compound, and a third conductive layer stacked in such a sequence, in which the intermetallic compound includes a first opening exposing the second conductive layer. The insulating layer is disposed on the conductive structure and includes a second opening exposing the second conductive layer of the conductive structure. The bonding structure is disposed on the insulating layer, in which the bonding structure is electrically connected to the conductive structure through the second opening of the insulating layer. A first width of the second opening of the insulating layer in a first direction is different from a second width of the intermetallic compound in the first direction.

In order to make the above features and advantages of the disclosure more comprehensible, embodiments are given below and described in detail with reference to the accompanying drawings.

### BRIEF DESCRIPTION OF THE DRAWINGS

FIG. 1A is a partial cross-sectional schematic view of an electronic device according to an embodiment of the disclosure.

FIG. 1B is an enlarged cross-sectional view of the first embodiment of a region R in FIG. 1A.

FIG. 2 is an enlarged cross-sectional view of the second embodiment of the region R in FIG. 1A.

FIG. 3 is an enlarged cross-sectional view of the third embodiment of the region R in FIG. 1A.

FIG. 4 is an enlarged cross-sectional view of the fourth embodiment of the region R in FIG. 1A.

FIG. 5 is an enlarged cross-sectional view of the fifth embodiment of the region R in FIG. 1A.

### DESCRIPTION OF THE EMBODIMENTS

The disclosure may be understood by referring to the following detailed description and combined with the accompanying drawings. It should be noted that, in order to make the readers easy to understand and the drawings to be concise, many of the drawings in the disclosure only depict a part of the electronic device, and certain elements in the drawings are not drawn to actual scale. In addition, the number and size of elements in the drawings are only for illustration and are not intended to limit the scope of the disclosure.

Certain words are used throughout the specification and appended claims to refer to specific elements. Persons skilled in the art will understand that electronic device manufacturers may refer to the same element by different names. The document is not intended to differentiate between elements that have the same function but have different names. In the following specification and appended claims, words such as “include”, “comprise”, and “have” are open-ended words, and should be interpreted as meaning “including but not limited to . . . ”. Therefore, when the words “include”, “comprise”, and/or “have” are used in the description of the disclosure, the words specify the presence of the corresponding features, regions, steps, operations, and/or components, but do not exclude the presence of one or more corresponding features, regions, steps, operations, and/or components.

The orientation terms mentioned in the document, such as “upper”, “lower”, “front”, “back”, “left”, “right”, are only for reference to the orientation of the accompanying drawings. Therefore, the orientation terms used is to illustrate, but not to limit, the disclosure. In the drawings, each figure illustrates the general features of methods, structures, and/or materials used in particular embodiments. However, the drawings should not be interpreted as defining or limiting the scope or nature encompassed by the embodiments. For example, the relative sizes, thicknesses, and locations of layers, regions, and/or structures may be reduced or enlarged for clarity.

When a corresponding component (such as a film layer or a region) is referred to as being “on” another component, the component may be directly on the other component, or other components may be present in between. On the other hand, when a component is said to be “directly on” another component, there are no components in between. In addition, when a component is said to be “on” another component, the components have a top-down relationship in the top-view orientation, and the component may be above or below the other component, and the top-down relationship depends on the orientation of the device.

The terms “about”, “substantially”, or “approximately” are generally interpreted to mean within 10% of a given value or range, or to mean within 5%, 3%, 2%, 1%, or 0.5% of a given value or range.

The ordinal numbers used in the specification and appended claims, such as “first” and “second”, are intended to modify elements. The numbers do not imply or suggest that the element(s) possess prior ordinal numbers, nor do they indicate the order of one element relative to another, or the sequence in a manufacturing method for the element(s). The use of the ordinal numbers is only intended to clearly distinguish an element with a certain name from another element with the same name. The same words may not be used in the specification and appended claims. Accordingly, a first component in the specification may be a second component in the appended claims.

It should be noted that the following embodiments may be replaced, reorganized, and mixed with features of several different embodiments to complete other embodiments without departing from the spirit of the disclosure. Features in various embodiments may be mixed and matched as long as the features do not violate the spirit of the disclosure or conflict with each other.

The electrical connection or coupling described in the disclosure may refer to direct connection or indirect connection. In the case of direct connection, the end points of the elements on the two circuits are directly connected or connected to each other through a conductor line segment; in the case of indirect connection, there are switches, diodes, capacitors, inductors, other suitable components, or combinations of the above elements between the end points of the elements on the two circuits, but are not limited thereto.

In the disclosure, the thickness, length, and width may be measured using an optical microscope, and the thickness may be measured using cross-sectional images in an electron microscope, but are not limited thereto. In addition, any two values or directions used for comparison may have certain errors. If a first value is equal to a second value, then it implies that there may be an error of about 10% between the first value and the second value; if a first direction is perpendicular to a second orientation, then the angle between the first direction and the second direction may be between 80 degrees and 100 degrees; if the first direction is parallel to the second direction, then the angle between the first direction and the second direction may be between 0 degrees and 10 degrees.

The electronic device of the disclosure may include an antenna device, a display device, a sensing device, a lighting device, or a splicing device, but is not limited thereto. The electronic device may include bendable or flexible electronic devices. The electronic device includes, for example, a liquid crystal layer or a light emitting diode (LED). The electronic device may include electronic components. The electronic component may include passive components and active components, for example, capacitors, resistors, inductors, variable capacitors, filters, diodes, transistors, sensors, MEMS, liquid crystal chips, but are not limited thereto. The diode may include light emitting diodes or photodiodes. The light emitting diode may include, for example, organic light emitting diodes (OLED), mini LEDs, micro LEDs, quantum dot LEDs, fluorescence, phosphor, or other suitable materials, or a combination of the above, but is not limited thereto. The sensor may include, for example, capacitive sensors, optical sensors, electromagnetic sensors, fingerprint sensors (FPS), touch sensors, antennas, or pen sensors, but is not limited thereto.

The following are examples of exemplary embodiments of the disclosure, in which an electronic device is represented by an antenna device for illustration, and the same reference numerals are used to denote the same or similar parts in the drawings and descriptions.

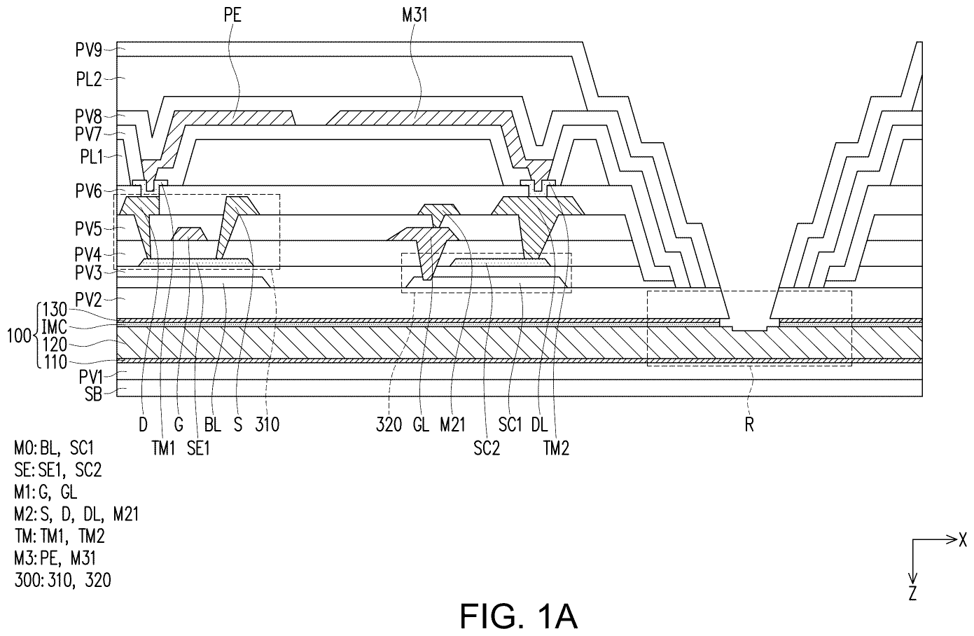

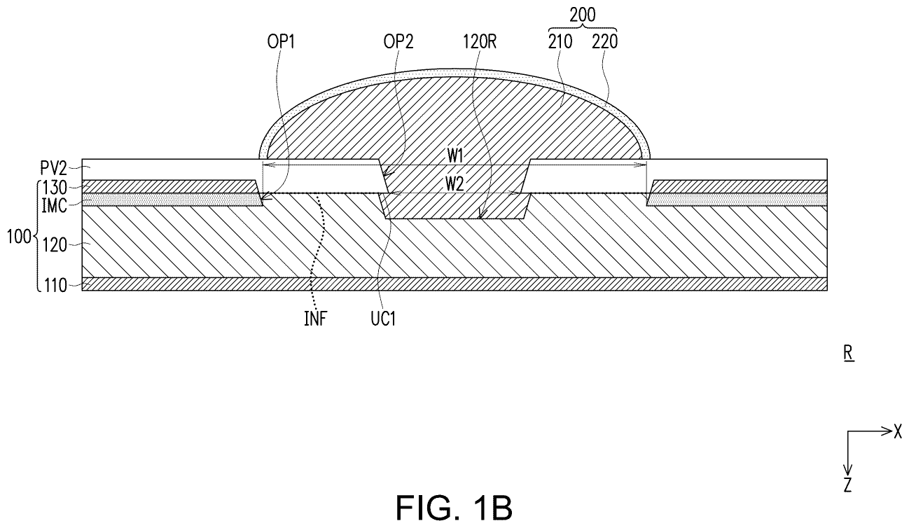

FIG. 1A is a partial cross-sectional schematic view of an electronic device according to an embodiment of the disclosure, and FIG. 1B is an enlarged cross-sectional view of the first embodiment of a region R in FIG. 1A.

Please refer to FIG. 1A together with FIG. 1B. An electronic device 10 of this embodiment includes a substrate SB, an insulating layer PV1, a conductive structure 100, an insulating layer PV2, a conductive layer M0, an insulating layer PV3, a semiconductor layer SE, an insulating layer PV4, a conductive layer M1, an insulating layer PV5, a conductive layer M2, an insulating layer PV6, a protective layer PL1, a conductive layer TM, an insulating layer PV7, a conductive layer M3, an insulating layer PV8, a protective layer PL1, an insulating layer PV9, and a bonding structure 200. From another perspective, the electronic device 10 of this embodiment includes a conductive structure 100, a bonding structure 200, and a drive unit 300, in which the insulating layer PV2 is disposed between the conductive structure 100 and the drive unit 300, and the bonding structure 200 is electrically connected to the conductive structure 100 exposed by an opening OP2 of the insulating layer PV2. In this embodiment, the drive unit 300 includes a drive element 310 and a storage capacitor 320, but the disclosure is not limited thereto. It is worth noting that the electronic device 10 of this embodiment may include, for example, an antenna device, a display device, a sensing device, a light emitting device, or a splicing device, but the disclosure is not limited thereto. In this embodiment, the electronic device 10 is an antenna device. For example, the electronic device 10 may be applied to the communication field, radar/lidar field, reconfigurable intelligent surface (RIS) technology, or other suitable fields/technologies, but the disclosure is not limited thereto. In some embodiments, the electronic device 10 may be a bendable or flexible electronic device, but the disclosure is not limited thereto.

The material of the substrate SB may be, for example, glass, plastic, or a combination thereof. For example, the material of the substrate SB may include quartz, sapphire, Si, Ge, SiC, GaN, SiGe, polymethyl methacrylate (PMMA), polycarbonate (PC), polyimide (PI), polyethylene terephthalate (PET), or other suitable materials or combinations of the above materials, and the disclosure is not limited thereto.

The insulating layer PV1 is disposed on the substrate SB, for example. In this embodiment, the material of the insulating layer PV1 is an inorganic material. For example, the material of the insulating layer PV1 may include silicon oxide, silicon nitride, silicon oxynitride, or a stacked layer of at least two of the above materials, but the disclosure is not limited thereto.

The conductive structure 100 is disposed on the insulating layer PV1, for example. In some embodiments, the conductive structure 100 may serve as a pad portion, a ground plate, an electrostatic protection layer, an electromagnetic interference shielding layer, a heat dissipation layer, other layers with different functions, or combinations thereof of the electronic device 10. In some embodiments, the conductive structure 100 may occupy more than 85% of the surface area of the substrate SB in a top-view direction Z of the substrate SB to shield electromagnetic waves that are not intended to be received, but the disclosure is not limited thereto. The material of the conductive structure 100 may include, for example, low-resistance materials such as copper, titanium, silver, gold, aluminum, tin, nickel, or combinations thereof. However, the material of the conductive structure 100 may also be other suitable materials or a combination of the above materials, and the disclosure is not limited thereto.

The conductive structure 100 includes, for example, a multi-layer structure. Referring to FIG. 1A together with FIG. 1B, in this embodiment, the conductive structure 100 includes a first conductive layer 110, a second conductive layer 120, and a third conductive layer 130 stacked in such a sequence, in which the material of the first conductive layer 110 is, for example, titanium nitride, the material of the second conductive layer 120 is, for example, copper, and the material of the third conductive layer 130 is, for example, titanium nitride. Since an active layer SE1 of the drive unit 300 undergoes a relatively high-temperature dehydrogenation process, the titanium in the third conductive layer 130 diffuses toward the direction close to the second conductive layer 120, resulting in the formation of an intermetallic compound IMC. Based on above, the conductive structure 100 further includes the intermetallic compound IMC disposed between the second conductive layer 120 and the third conductive layer 130.

The intermetallic compound IMC includes, for example, an opening OP1 exposing the second conductive layer 120. In this embodiment, the opening OP1 exposing the second conductive layer 120 is formed before the active layer SE1 of the drive element 310 is formed. That is, the intermetallic compound IMC is not yet formed between the second conductive layer 120 and the third conductive layer 130 at this time, and the opening OP1 exposing the second conductive layer 120 may be formed by performing a simple patterning process on the third conductive layer 130. In some embodiments, the opening OP1 of the intermetallic compound IMC has a width W1 in a direction X. In this embodiment, the width W1 is 87 microns, but the disclosure is not limited thereto.

In this embodiment, the second conductive layer 120 includes a recess 120R. The recess 120R of the second conductive layer 120, for example, at least partially overlaps the opening OP1 of the intermetallic compound IMC in the top-view direction Z of the SB. Since the opening OP2 of the insulating layer PV2, which will be introduced later, is formed after the opening OP1 of the intermetallic compound IMC is formed, during the process of forming the opening OP2 of the insulating layer PV2, a part of the second conductive layer 120 exposed by the opening OP1 is also removed, resulting in the formation of the recess 120R of the second conductive layer 120.

The insulating layer PV2 is, for example, disposed on the conductive structure 100, and includes, for example, the opening OP2 exposing the conductive structure 100. In this embodiment, the material of the insulating layer PV2 is an inorganic material. For example, the material of the insulating layer PV2 may include silicon oxide, silicon nitride, silicon oxynitride, or a stacked layer of at least two of the above materials, but the disclosure is not limited thereto.

In some embodiments, the opening OP2 of the insulating layer PV2 has a width W2 in a direction X. In this embodiment, the width W2 is 80 microns, but the disclosure is not limited thereto. For example, the width W2 of the opening OP2 of the insulating layer PV2 in the direction X is different from the width W1 of the opening OP1 of the intermetallic compound IMC in the direction X. Referring to FIG. 1B, in this embodiment, the width W2 of the opening OP2 of the insulating layer PV2 in the direction X is smaller than the width W1 of the opening OP1 of the intermetallic compound IMC in the direction X, and the opening OP2 of the insulating layer PV2 overlaps with the opening OP1 of the intermetallic compound IMC in the top-view direction Z of the SB. Based on above, the insulating layer PV2 may be in contact with the second conductive layer 120 exposed by the intermetallic compound IMC. In some embodiments, an interface INF in contact between the insulating layer PV2 and the second conductive layer 120 may be a copper oxide interface, which is formed due to the reaction between the etching gas and copper during the formation of the opening OP2 of the insulating layer PV2 using an etching process, but the disclosure is not limited thereto. In other embodiments, the interface INF in contact between the insulating layer PV2 and the second conductive layer 120 may be a copper rough surface, which is formed due to corrosion of copper by the etching gas during the formation of the opening OP2 of the insulating layer PV2 using the etching process.

In this embodiment, since the opening OP2 of the insulating layer PV2 is formed after the opening OP1 of the intermetallic compound IMC is formed, the insulating layer PV2 includes an undercut UC1. In detail, the opening OP2 of the insulating layer PV2 overlaps with the recess 120R of the second conductive layer 120 in the top-view direction Z of the SB, and the width W2 of the opening OP2 of the insulating layer PV2 in the direction X is smaller than the width of the recess 120R of the second conductive layer 120 in the direction X. The width of the undercut UC1 of the insulating layer PV2 in the direction X may be, for example, 0.2 microns to 0.3 microns, but the disclosure is not limited thereto.

In some embodiments, the insulating layer PV1 and the insulating layer PV2 may be made from materials with appropriate thermal expansion coefficients; or from materials that counteract the stress generated when the conductive structure 100 undergoes the heating process; or alternatively, from materials that exhibit good adhesion to the conductive structure 100. Based on above, the insulating layer PV1 and the insulating layer PV2 respectively disposed below and above the conductive structure 100 can have a stress control effect, which can be used to reduce the possibility of substrate warping. In detail, since the electronic device 10 undergoes multiple heating processes (including the above-mentioned process of forming the active layer SE1 of the drive element 310) during the formation of the electronic device 10, and the material included in the conductive structure 100 has a thermal expansion coefficient greater than a thermal expansion coefficient of the substrate SB, the edge of the substrate SB tends to warp toward the direction facing the conductive structure 100. Based on above, the warping phenomenon generated in the substrate SB can be reduced by disposing the insulating layer PV1 and the insulating layer PV2.

The conductive layer M0 is disposed, for example, on the insulating layer PV2. In this embodiment, the conductive layer M0 includes a light blocking layer BL and a storage electrode SC1 of the storage capacitor 320. The light blocking layer BL is, for example, positioned between the substrate SB and the channel area of the active layer SE1 of the drive element 310, and at least partially overlaps with the channel area of the active layer SE1 in the top-view direction Z of the substrate SB, which can reduce the impact and deterioration of the channel area of the active layer SE1 due to exposure to external ambient light. In some embodiments, the material of the conductive layer M0 may include a material with a transmittance of less than 30%, but the disclosure is not limited thereto.

The insulating layer PV3 is disposed on the insulating layer PV2, for example. In this embodiment, the insulating layer PV3 covers the light blocking layer BL and covers part of the storage electrode SC1, but the disclosure is not limited thereto. In this embodiment, the material of the insulating layer PV3 is an inorganic material. For example, the material of the insulating layer PV3 may include silicon oxide, silicon nitride, silicon oxynitride, or a stacked layer of at least two of the above materials, but the disclosure is not limited thereto. In this embodiment, the insulating layer PV3 is a stacked layer formed by a silicon oxide layer and a silicon nitride layer.

The semiconductor layer SE is disposed on the insulating layer PV3, for example. In this embodiment, the material of the semiconductor layer SE includes low temperature polysilicon (LTPS), but the disclosure is not limited thereto. In other embodiments, the material of the semiconductor layer SE may include, but is not limited to, amorphous silicon, germanium, compound semiconductors (such as gallium nitride, silicon carbide, gallium arsenide, gallium phosphide, indium phosphide, indium arsenide, and/or indium antimonide), alloy semiconductors (such as SiGe alloy, GaAsP alloy, AlInAs alloy, AlGaAs alloy, GaInAs alloy, GaInP alloy, and GaInAsP alloy), or a combination of the above. The material of the semiconductor layer SE may also include but is not limited to metal oxides, such as IGZO, IZO, IGZTO, or organic semiconductors containing polycyclic aromatic compounds, or a combination of the above. In this embodiment, the semiconductor layer SE includes the active layer SE1 of the drive element 310 and a storage electrode SC2 of the storage capacitor 320. In detail, in this embodiment, the storage capacitor 320 is formed by the storage electrode SC1, the storage electrode SC2, and the insulating layer PV3 disposed between the storage electrode SC1 and the storage electrode SC2.

The insulating layer PV4 is disposed on the insulating layer PV3, for example. In this embodiment, the insulating layer PV4 covers part of the active layer SE1 and part of the storage electrode SC2, but the disclosure is not limited thereto. In this embodiment, the material of the insulating layer PV4 is an inorganic material. For example, the material of the insulating layer PV4 may include silicon oxide, silicon nitride, silicon oxynitride, or a stacked layer of at least two of the above materials, but the disclosure is not limited thereto. In this embodiment, the insulating layer PV4 is a stacked layer formed by a silicon oxide layer and a silicon nitride layer.

The conductive layer M1 is disposed on the insulating layer PV4, for example. In this embodiment, the conductive layer M1 includes a gate G of the drive element 310 and a gate line GL. The gate G, for example, at least partially overlaps the active layer SE1 in the top-view direction Z of the substrate SB. The gate line GL is, for example, electrically connected to the gate G of the drive element 310 for providing a corresponding gate voltage to the drive element 310. In addition, in this embodiment, the gate line GL may be electrically connected to the storage electrode SC1 of the storage capacitor 320 through an opening connected in the insulating layer PV3 and the insulating layer PV4.

The insulating layer PV5 is disposed on the insulating layer PV4, for example. In this embodiment, the insulating layer PV5 covers the gate G and part of the gate line GL, but the disclosure is not limited thereto. In this embodiment, the material of the insulating layer PV5 is an inorganic material. For example, the material of the insulating layer PV5 may include silicon oxide, silicon nitride, silicon oxynitride, or a stacked layer of at least two of the above materials, but the disclosure is not limited thereto. In this embodiment, the insulating layer PV5 is a stacked layer formed by a silicon oxide layer and a silicon nitride layer.

The conductive layer M2 is disposed on the insulating layer PV5, for example. In this embodiment, the conductive layer M2 includes a source S and a drain D of the drive element 310 and a data line DL. The source S and the drain D are, for example, separated from each other and cover at least part of the active layer SE1. In this embodiment, the source S and the drain D may be electrically connected to the active layer SE1 through an opening connected in the insulating layer PV4 and the insulating layer PV5, but the disclosure is not limited thereto. The data line DL is, for example, electrically connected to the source S of a drive element DC of the drive element 310 for providing a corresponding data voltage to the drive element 310. In addition, in this embodiment, the data line DL may be electrically connected to the storage electrode SC2 of the storage capacitor 320 through another opening connected in the insulating layer PV4 and the insulating layer PV5. In some embodiments, the conductive layer M2 further includes a conductive layer M21, which may be electrically connected to the gate line GL through an opening in the insulating layer PV5. The disposition of the conductive layer M21 can increase the cross-sectional area of the gate line GL, thereby reducing the impedance value generated by the gate line GL (the impedance value is inversely proportional to the cross-sectional area of the conductive layer), thereby improving the signal transmission quality of the drive element 310.

In this embodiment, the drive element 310 is formed by the gate G, the source S, the drain D, and the active layer SE1. It is worth noting that although this embodiment shows that the drive element 310 may be any top-gate thin film transistor well known to persons skilled in the art, the disclosure is not limited thereto.

The insulating layer PV6 is disposed on the insulating layer PV5, for example. In this embodiment, the insulating layer PV6 covers the drain D and the conductive layer M21, and covers part of the source S and part of the data line DL, but the disclosure is not limited thereto. In this embodiment, the material of the insulating layer PV6 is an inorganic material. For example, the material of the insulating layer PV6 may include silicon oxide, silicon nitride, silicon oxynitride, or a stacked layer of at least two of the above materials, but the disclosure is not limited thereto.

A conductive layer TM is disposed on the insulating layer PV6, for example. In this embodiment, the conductive layer TM may include a conductive layer TM1 and a conductive layer TM2, in which the conductive layer TM1 and the conductive layer TM2 are each electrically connected to the drain D and the data line DL exposed by the insulating layer PV6, but the disclosure is not limited thereto. The material of the conductive layer TM may be, for example, metal oxide. For example, the material of the conductive layer TM may include indium tin oxide, but the disclosure is not limited thereto.

The protective layer PL1 is disposed on the insulating layer PV6, for example. In this embodiment, the protective layer PL1 includes an opening exposing the conductive layer TM, but the disclosure is not limited thereto. In this embodiment, the material of the protective layer PL1 is an organic material. For example, the material of the protective layer PL1 may include polyimide resin, epoxy resin, acrylic resin, or a stacked layer of at least two of the above materials, but the disclosure is not limited thereto.

The insulating layer PV7 is disposed on the protective layer PL1, for example. In this embodiment, the insulating layer PV7 is disposed in the opening of the protective layer PL1 and covers part of the conductive layer TM, but the disclosure is not limited thereto. In this embodiment, the material of the insulating layer PV7 is an inorganic material. For example, the material of the insulating layer PV7 may include silicon oxide, silicon nitride, silicon oxynitride, or a stacked layer of at least two of the above materials, but the disclosure is not limited thereto.

The conductive layer M3 is disposed on the insulating layer PV7, for example. In this embodiment, the conductive layer M3 includes a pixel electrode PE. In this embodiment, the pixel electrode PE may be electrically connected to the drain D of the drive element 310 through the opening of the insulating layer PV7 to receive a pixel voltage from the drive element 310, but the disclosure is not limited thereto. In some embodiments, the conductive layer M3 further includes a conductive layer M31, which may be electrically connected to the data line DL through another opening in the insulating layer PV7. The disposition of the conductive layer M31 can increase the cross-sectional area of the data line DL, thereby reducing the impedance value generated by the data line DL (the impedance value is inversely proportional to the cross-sectional area of the conductive layer), thereby improving the signal transmission quality of the drive element 310.

The insulating layer PV8 is disposed on the insulating layer PV7, for example. In this embodiment, the insulating layer PV8 covers the conductive layer M3, but the disclosure is not limited thereto. In this embodiment, the material of the insulating layer PV8 is an inorganic material. For example, the material of the insulating layer PV8 may include silicon oxide, silicon nitride, silicon oxynitride, or a stacked layer of at least two of the above materials, but the disclosure is not limited thereto.

A protective layer PL2 is disposed on the insulating layer PV8, for example. In this embodiment, the protective layer PL2 covers the insulating layer PV8, but the disclosure is not limited thereto. In this embodiment, the material of the protective layer PL2 is an organic material. For example, the material of the protective layer PL2 may include polyimide resin, epoxy resin, acrylic resin, or a stacked layer of at least two of the above materials, but the disclosure is not limited thereto.

The insulating layer PV9 is disposed on the protective layer PL2, for example. In this embodiment, the insulating layer PV9 covers the protective layer PL2, but the disclosure is not limited thereto. In this embodiment, the material of the insulating layer PV9 is an inorganic material. For example, the material of the insulating layer PV9 may include silicon oxide, silicon nitride, silicon oxynitride, or a stacked layer of at least two of the above materials, but the disclosure is not limited thereto.

The bonding structure 200 is disposed on the insulating layer PV2, for example, and is electrically connected to the conductive structure 100 through, for example, the opening OP2 of the insulating layer PV2. In some embodiments, the bonding structure 200 at least partially overlaps with at least one of the opening OP1 of the intermetallic compound IMC and the opening OP2 of the insulating layer PV2 in the top-view direction Z of the substrate SB. In this embodiment, the bonding structure 200 overlaps with the opening OP1 of the intermetallic compound IMC and the opening OP2 of the insulating layer PV2 in the top-view direction Z of the substrate SB. The bonding structure 200 includes, for example, a conductive layer 210 and a conductive layer 220 disposed on the conductive layer 210, in which the materials of the conductive layer 210 and the conductive layer 220 may include, for example, metal or alloy. In this embodiment, the bonding structure 200 is formed by performing an electroless nickel immersion gold (ENIG) process. Based on above, the material of the conductive layer 210 is nickel, while the material of the conductive layer 220 is gold, but the disclosure is not limited thereto.

In some embodiments, a chip (not shown) may be disposed on the bonding structure 200, but the disclosure is not limited thereto. The chip may include communication components, for example. In some embodiments, the chip may include varactors, variable capacitors, radio frequency radiation elements, variable resistors, phase shifters, amplifiers, antennas, biometric sensors, graphene sensors, other suitable components, or combinations thereof, but the disclosure is not limited thereto. For example, the chip may be a varactor. The varactor may provide different capacitance values based on the signal provided by a drive element that will be introduced later. That is, the capacitance value of the varactor can be changed by changing the voltage across the varactor. Therefore, by adjusting the capacitance value of the varactor, the electronic device 10 of this embodiment can adjust the operating frequency band, but the disclosure is not limited thereto.

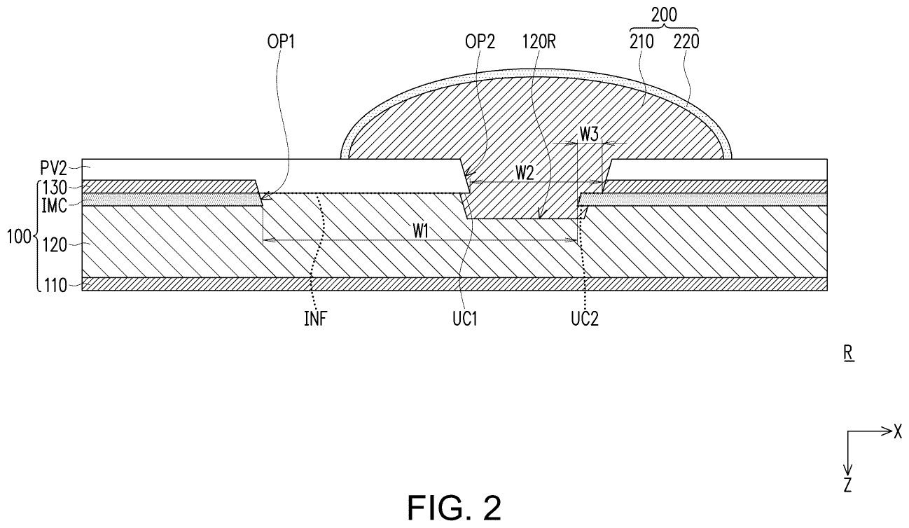

FIG. 2 is an enlarged cross-sectional view of the second embodiment of the region R in FIG. 1A. The embodiment of FIG. 2 may continue to use reference numerals and part of the content of the embodiment of FIG. 1B, the same or similar reference numerals are used to represent the same or similar parts, and descriptions of the same technical content are omitted.

Please refer to FIG. 2. The main difference between this embodiment and the embodiment shown in FIG. 1A is that: the opening OP2 of the insulating layer PV2 exposes part of the intermetallic compound IMC.

In detail, in this embodiment, the opening OP2 of the insulating layer PV2 formed through the patterning process is offset in the direction X and does not completely overlap with the opening OP1 of the intermetallic compound IMC. Based on above, during the process of forming the opening OP2 of the insulating layer PV2, a part of the third conductive layer 130 is removed, and the intermetallic compound IMC may serve as an etching stop layer, so that the opening OP2 of the insulating layer PV2 exposes part of the intermetallic compound IMC. However, the disclosure is not limited thereto. In other embodiments, the third conductive layer 130 may serve as the etching stop layer, so that the opening OP2 of the insulating layer PV2 exposes part of the third conductive layer 130.

The intermetallic compound IMC exposed by the opening OP2 of the insulating layer PV2 has a width W3 in the direction X, for example. In this embodiment, the width W3 of the exposed intermetallic compound IMC is 0.5 microns, but the disclosure is not limited thereto. In addition, in this embodiment, the exposed intermetallic compound IMC also includes an undercut UC2. The width of the undercut UC2 of the intermetallic compound IMC in the direction X may be, for example, 0.2 microns to 0.3 microns, but the disclosure is not limited thereto.

In this embodiment, the bonding structure 200 is in contact with the intermetallic compound IMC exposed by the opening OP2 of the insulating layer PV2. There is relatively good adhesion between the conductive layer 210 of the bonding structure 200 and the exposed intermetallic compound IMC. Furthermore, the intermetallic compound IMC exposed by the opening OP2 of the insulating layer PV2 can have relatively good water and oxygen blocking properties. Based on above, through the bonding structure 200 being in contact with the intermetallic compound IMC, the reliability of the electrical connection between the bonding structure 200 and the conductive structure 100 can be increased.

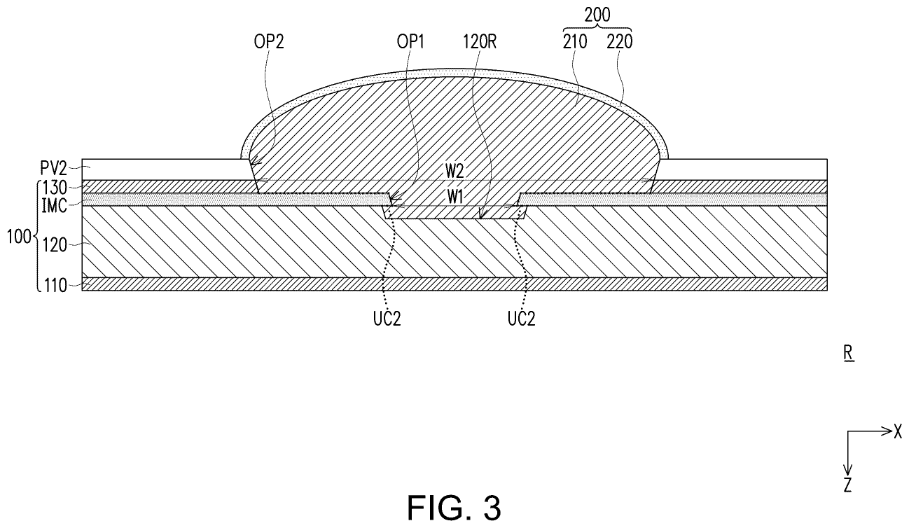

FIG. 3 is an enlarged cross-sectional view of the third embodiment of the region R in FIG. 1A. The embodiment of FIG. 3 may continue to use reference numerals and part of the content of the embodiment of FIG. 2, the same or similar reference numerals are used to represent the same or similar parts, and descriptions of the same technical content are omitted.

Please refer to FIG. 3. The main difference between this embodiment and the embodiment shown in FIG. 2 is that: the width W2 of the opening OP2 of the insulating layer PV2 in the direction X is greater than the width W1 of the opening OP1 of the intermetallic compound IMC on the direction X.

Based on above, in this embodiment, the conductive layer 210 of the bonding structure 200 and the intermetallic compound IMC may have a relatively large bonding area, which can further increase the reliability of the electrical connection between the bonding structure 200 and the conductive structure 100.

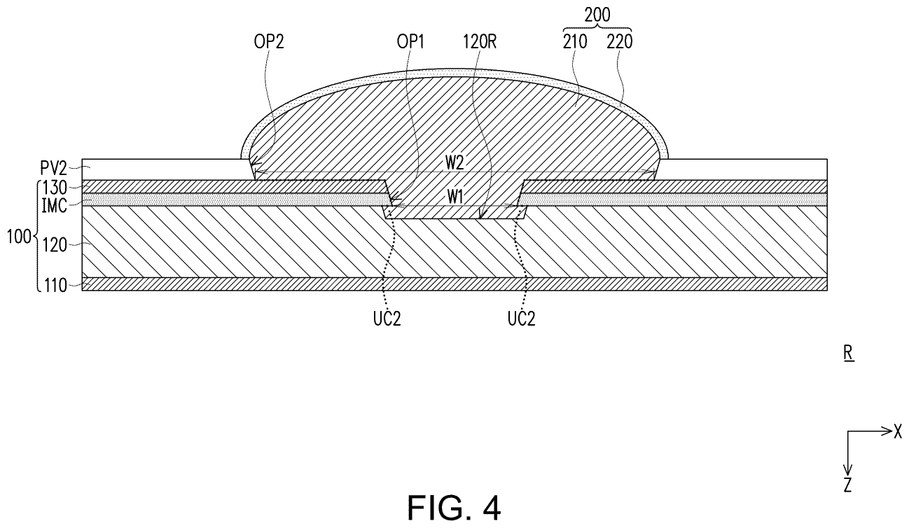

FIG. 4 is an enlarged cross-sectional view of the fourth embodiment of the region R in FIG. 1A. The embodiment of FIG. 4 may continue to use reference numerals and part of the content of the embodiment of FIG. 3, the same or similar reference numerals are used to represent the same or similar parts, and descriptions of the same technical content are omitted.

Please refer to FIG. 4. The main difference between this embodiment and the embodiment shown in FIG. 3 is that: the opening OP2 of the insulating layer PV2 exposes part of the third conductive layer 130.

In detail, in this embodiment, the third conductive layer 130 serves as the etching stop layer during the process of forming the opening OP2 of the insulating layer PV2. Therefore, after the opening OP2 of the insulating layer PV2 is formed, the opening OP2 of the insulating layer PV2 exposes part of the third conductive layer 130. In this embodiment, the bonding structure 200 is in contact with the third conductive layer 130 exposed by the opening OP2 of the insulating layer PV2. Similar to the embodiment shown in FIG. 2, due to the relatively good adhesion between the conductive layer 210 of the bonding structure 200 and the exposed third conductive layer 130, the adhesion between the bonding structure 200 and the conductive structure 100 can be increased, and the reliability of the electrical connection between the bonding structure 200 and the conductive structure 100 can be increased.

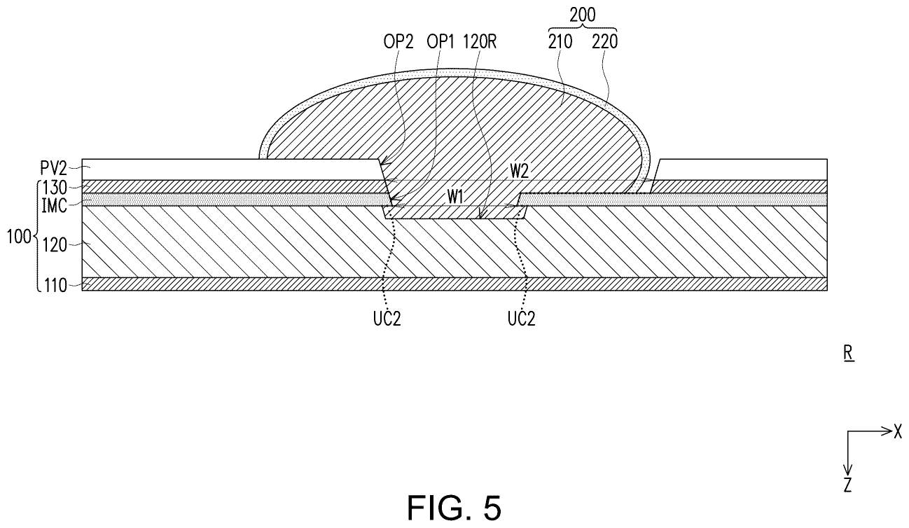

FIG. 5 is an enlarged cross-sectional view of the fifth embodiment of the region R in FIG. 1A. The embodiment of FIG. 5 may continue to use reference numerals and part of the content of the embodiment of FIG. 3, the same or similar reference numerals are used to represent the same or similar parts, and descriptions of the same technical content are omitted.

Please refer to FIG. 5. The main difference between this embodiment and the embodiment shown in FIG. 3 is that: a side of the opening OP2 of the insulating layer PV2 is aligned with a side of the opening OP1 of the intermetallic compound IMC.

In this embodiment, since the side of the opening OP2 of the insulating layer PV2 is aligned with the side of the opening OP1 of the intermetallic compound IMC, the opposite side of the opening OP2 of the insulating layer PV2 exposes more of the intermetallic compound IMC. In some embodiments, the bonding structure 200 may expose part of the intermetallic compound IMC located on the opposite side of the opening OP2 of the insulating layer PV2, but the disclosure is not limited thereto.

In addition, in some embodiments, the third conductive layer 130 may serve as the etching stop layer during the process of forming the opening OP2 of the insulating layer PV2. Based on above, in other embodiments, after the opening OP2 of the insulating layer PV2 is formed, the opening OP2 of the insulating layer PV2 exposes part of the third conductive layer 130.

In summary, in the electronic device provided by some embodiments of the disclosure, the opening of the copper layer exposing the conductive structure is formed before the active layer of the drive element is formed. Therefore, the intermetallic compound is not yet formed between the copper layer and the titanium nitride layer at this time, and the opening exposing the copper layer may be formed through a simple patterning process. Furthermore, the subsequently formed bonding structure may have relatively good electrical connection with the conductive layer, which can improve the reliability of the electronic device provided by some embodiments of the disclosure.

In the electronic device provided by other embodiments of the disclosure, the opening of the insulating layer exposes part of the intermetallic compound. There is relatively good adhesion between the bonding structure and the exposed intermetallic compound. Furthermore, the intermetallic compound exposed by the opening of the insulating layer can have relatively good water and oxygen blocking properties, which can further improve the reliability of the electrical connection between the bonding structure and the conductive layer in the electronic device provided by some embodiments of the disclosure.

What is claimed is:

1. An electronic device, comprising:
a substrate;
a conductive structure disposed on the substrate and comprising a first conductive layer, a second conductive layer, an intermetallic compound, and a third conductive layer stacked in such a sequence, wherein the intermetallic compound comprises a first opening exposing the second conductive layer;
an insulating layer disposed on the conductive structure and comprising a second opening exposing the second conductive layer of the conductive structure; and
a bonding structure disposed on the insulating layer, wherein the bonding structure is electrically connected to the conductive structure through the second opening of the insulating layer,
wherein a first width of the second opening of the insulating layer in a first direction is different from a second width of the first opening of the intermetallic compound in the first direction.

2. The electronic device as claimed in claim 1, wherein the first width is greater than the second width.

3. The electronic device as claimed in claim 1, wherein the first width is smaller than the second width.

4. The electronic device as claimed in claim 1, wherein the second conductive layer comprises a recess, and the recess at least partially overlaps with the first opening of the intermetallic compound.

5. The electronic device as claimed in claim 4, wherein the first width of the second opening of the insulating layer in the first direction is smaller than a width of the recess of the second conductive layer in the first direction.

6. The electronic device as claimed in claim 1, wherein the insulating layer has an undercut.

7. The electronic device as claimed in claim 6, wherein a width of the undercut of the insulating layer in the first direction is 0.2 microns to 0.3 microns.

8. The electronic device as claimed in claim 1, wherein the insulating layer further exposes the third conductive layer of the conductive structure, and the bonding structure is in contact with the third conductive layer.

9. The electronic device as claimed in claim 1, wherein the insulating layer further exposes the intermetallic compound of the conductive structure, and the bonding structure is in contact with the intermetallic compound.

10. The electronic device as claimed in claim 9, wherein the intermetallic compound has an undercut.

11. The electronic device as claimed in claim 10, wherein a width of the undercut of the intermetallic compound in the first direction is 0.2 microns to 0.3 microns.

12. The electronic device as claimed in claim 1, wherein a side of the second opening of the insulating layer is aligned with a side of the first opening of the intermetallic compound.

13. The electronic device as claimed in claim 12, wherein the insulating layer further exposes the intermetallic compound of the conductive structure, and the bonding structure is in contact with the intermetallic compound.

14. The electronic device as claimed in claim 12, wherein the intermetallic compound has an undercut.

15. The electronic device as claimed in claim 14, wherein a width of the undercut of the intermetallic compound in the first direction is 0.2 microns to 0.3 microns.

16. The electronic device as claimed in claim 1, wherein the insulating layer is in contact with the second conductive layer exposed by the intermetallic compound.

17. The electronic device as claimed in claim 16, wherein an interface in contact between the insulating layer and the second conductive layer is a copper oxide interface.

18. The electronic device as claimed in claim 16, wherein an interface in contact between the insulating layer and the second conductive layer is a copper rough surface.

19. The electronic device as claimed in claim 1, wherein a material of the first conductive layer is titanium nitride, a material of the second conductive layer is copper, and a material of the third conductive layer is titanium nitride.

20. The electronic device as claimed in claim 1, wherein the bonding structure is formed by performing an electroless nickel immersion gold process.
